(19) United States
(12) Patent Application Publication
(10) Pub. No.: US 2015/0103494 A1
(43) Pub. Date: Apr. 16, 2015

(54) PRINTED CIRCUIT BOARDS HAVING METAL LAYERS AND SEMICONDUCTOR PACKAGES INCLUDING THE SAME

(71) Applicant: SAMSUNG ELECTRONICS CO., LTD., Suwon-si (KR)

(72) Inventors: Hee-jeong Kim, Seoul (KR); Eun-Chul AHN, Yongin-si (KR); Yong-Kwan LEE, Hwaseong-si (KR)

(73) Assignee: SAMSUNG ELECTRONICS CO., LTD., Suwon-si (KR)

(21) Appl. No.: 14/513,436

(22) Filed: Oct. 14, 2014

(30) Foreign Application Priority Data
Oct. 14, 2013 (KR) 10-2013-0122194

(51) Int. Cl. H05K 1/11; H05K 1/18; H05K 1/09

(52) U.S. Cl. CPC H05K 1/115; H05K 1/09; H05K 1/181
USPC 361/728; 174/261; 174/257

(57) ABSTRACT

Printed circuit boards are provided. The printed circuit board includes an insulation layer, an interconnection portion and a metal layer. The insulation layer has a flat plate shape and includes a top surface and a bottom surface. The interconnection portion is disposed on at least one of the top and bottom surfaces of the insulation layer. The interconnection portion includes a plurality of interconnection patterns. The metal layer covers the plurality of interconnection patterns of the interconnection portion. Related semiconductor packages are also provided.

### CROSS-REFERENCE TO RELATED APPLICATIONS

This application claims priority from Korean Patent Application No. 10-2013-0122194, filed on Oct. 14, 2013, in the Korean Intellectual Property Office, the disclosure of which is incorporated herein by reference, in its entirety.

### BACKGROUND

The exemplary embodiments relate to semiconductor packages. More particularly, the exemplary embodiments relate to printed circuit boards (PCBs) having metal layers and semiconductor packages including the same.

Semiconductor packages may be fabricated by electrically connecting pads of integrated circuit devices to exterior terminals of package substrates and by encapsulating the integrated circuit devices with a protection material such as a molding compound. That is, each of the semiconductor packages may be fabricated to include at least one semiconductor chip, a printed circuit board (PCB) on which the at least one semiconductor chip is mounted, and a molding member encapsulating the at least one semiconductor chip.

The PCB may be fabricated to include an insulation substrate and conductive interconnection lines disposed in and/or on the insulation substrate.

### SUMMARY

The exemplary embodiments provide printed circuit boards (PCBs) and semiconductor packages including the same.

According to an aspect of the exemplary embodiments, there is provided a printed circuit board. The printed circuit board includes an insulation layer, an interconnection portion and a metal layer. The insulation layer has a flat plate shape and includes a top surface and a bottom surface. The interconnection portion is disposed on at least one of the top and bottom surfaces of the insulation layer. The interconnection portion includes a plurality of interconnection patterns. The metal layer covers the plurality of interconnection patterns constituting the interconnection portion.

In some exemplary embodiments, the printed circuit board may further include a protection layer that covers the top and bottom surfaces of the insulation layer and a surface of the metal layer.

In some exemplary embodiments, the protection layer may include any one of a solder resist (SR) material, a dry film resist (DFR) material, an electro-deposition resist material and a screen resist material.

In some exemplary embodiments, the insulation layer may include at least one internal interconnection pattern layer disposed therein.

In some exemplary embodiments, the interconnection portion may be disposed in the insulation layer to provide a buried type configuration or may be disposed on a surface of the insulation layer to provide a normal type configuration.

In some exemplary embodiments, the interconnection portion may include an aluminum material or a copper material.

In some exemplary embodiments, the metal layer may include at least one of a tin (Sn) material, a nickel (Ni) material, a titanium (Ti) material, a titanium nitride (TiN) material, a tantalum (Ta) material, a tantalum nitride (TaN) material, a titanium tungsten (TiW) material and a tungsten nitride (WN) material.

According to another aspect of the exemplary embodiments, there is provided a semiconductor package. The semiconductor package includes a printed circuit board including a plurality of interconnection patterns and a metal layer covering the plurality of interconnection patterns, a semiconductor chip mounted on at least one of a top surface and a bottom surface of the printed circuit board using a wire bonding technique or a flip-chip bonding technique, and a molding member covering at least one of the top and bottom surfaces of the printed circuit board.

In some exemplary embodiments, the printed circuit board may further include an insulation layer and an interconnection portion. The insulation layer may have a flat plate shape and may include a top surface and a bottom surface. The interconnection portion may be disposed on at least one of the top and bottom surfaces of the insulation layer, and the interconnection portion may include the plurality of interconnection patterns. The interconnection portion may be disposed in the insulation layer to provide a buried type configuration or may be disposed on a surface of the insulation layer to provide a normal type configuration.

In some exemplary embodiments, the semiconductor package may further include an adhesive layer disposed between the printed circuit board and the semiconductor chip.

In some exemplary embodiments, the metal layer of the printed circuit board may include at least one of a tin (Sn) material, a nickel (Ni) material, a titanium (Ti) material, a titanium nitride (TiN) material, a tantalum (Ta) material, a tantalum nitride (TaN) material, a titanium tungsten (TiW) material and a tungsten nitride (WN) material.

In some exemplary embodiments, the molding member may be disposed to expose a top surface of the semiconductor chip.

In some exemplary embodiments, the molding member may include an internal molding member and an external molding member. The internal molding member may fill a space between the semiconductor chip and the printed circuit board, and the external molding member may cover the semiconductor chip. The internal molding member and the external molding member may include the same material.

In some exemplary embodiments, the molding member may include an external molding member covering the semiconductor chip and an under-fill material filling a space between the semiconductor chip and the printed circuit board.

In some exemplary embodiments, the semiconductor package may further include at least one upper semiconductor chip stacked on a surface of the semiconductor chip opposite to the printed circuit board.

An aspect of an exemplary embodiment may provide a printed circuit board including: an interconnection portion including a plurality of interconnection patterns; and a metal layer covering the plurality of interconnection patterns of the interconnection portion, wherein the metal layer includes at least one of a tin (Sn) material, a nickel (Ni) material, a titanium (Ti) material, a titanium nitride (TiN) material, a tantalum (Ta) material, a tantalum nitride (TaN) material, a titanium tungsten (TiW) material and a tungsten nitride (WN) material.

The printed circuit board may further include an insulation layer having a flat plate shape and including a top surface and a bottom surface.

The interconnection portion may be formed on at least one of top and bottom surfaces of the insulation layer.

The printed circuit board may further include a protection layer covering the top and bottom surfaces of the insulation layer and a surface of the metal layer.

The protection layer may include any one of a solder resist (SR) material, a dry film resist (DFR) material, an electro-deposition resist material and a screen resist material.

### BRIEF DESCRIPTION OF THE DRAWINGS

The exemplary embodiments will be more clearly understood from the following detailed description taken in conjunction with the accompanying drawings in which:

FIG. 1 is a cross-sectional view illustrating a semiconductor package according to an exemplary embodiment;

FIGS. 2A and 2B are cross-sectional views which illustrate printed circuit boards according to an exemplary embodiment;

FIGS. 3A to 3D are cross-sectional views which illustrate a method of fabricating a printed circuit board according to an exemplary embodiment;

FIG. 4 is a plan view which illustrates a printed circuit board according to an exemplary embodiment;

FIG. 5 is a cross-sectional view taken along a line I-I of FIG. 4;

FIGS. 6A and 6B are cross-sectional views which illustrate printed circuit boards according to an exemplary embodiment;

FIGS. 7A to 7D are cross-sectional views which illustrate a method of fabricating a printed circuit board according to an exemplary embodiment;

FIG. 8 is a cross-sectional view which illustrates a printed circuit board according to an exemplary embodiment;

FIGS. 9A and 9B are cross-sectional views which illustrate printed circuit boards according to an exemplary embodiment;

FIGS. 10 to 16 are cross-sectional views which illustrate semiconductor packages according to an exemplary embodiment;

FIG. 17 is a block diagram which illustrates a memory card including a semiconductor package according to an exemplary embodiment;

FIG. 18 is a block diagram which illustrates a system including a semiconductor package according to an exemplary embodiment;

FIG. 19 is a plan view which illustrates a semiconductor module including a plurality of semiconductor packages according to an exemplary embodiment; and

FIG. 20 is a cross-sectional view which illustrates a semiconductor module including a plurality of semiconductor packages according to an exemplary embodiment.

### DETAILED DESCRIPTION OF THE EXEMPLARY EMBODIMENTS

Various exemplary embodiments will now be described more fully hereinafter with reference to the accompanying drawings. In the following descriptions, it will be understood that when an element such as a layer, region or substrate is referred to as being “on” another element, it can be directly on the other element or intervening elements may be present. In the drawing figures, the size of each element may be exaggerated for clarity of illustration and portions having no relation with the explanation may be omitted. Moreover, in the drawing figures, the same reference numerals or the same reference designators denote the same elements. The terminology used herein is for the purpose of describing particular embodiments only and is not intended to limit the scope of the exemplary embodiments.

Expressions such as “at least one of,” when preceding a list of elements, modify the entire list of elements and do not modify the individual elements of the list.

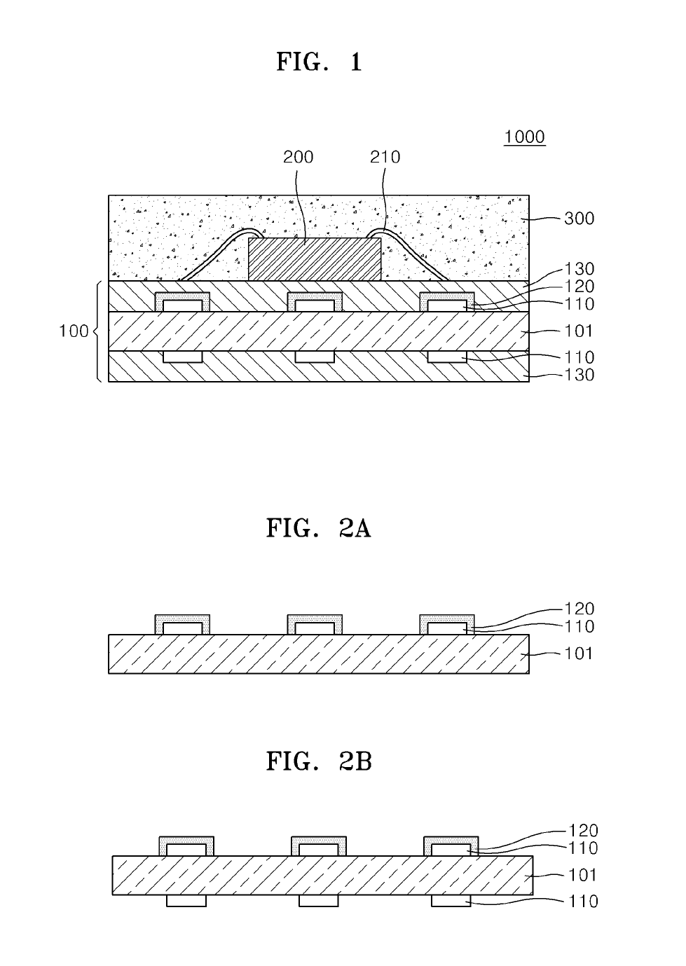

FIG. 1 is a cross-sectional view which illustrates a semiconductor package according to an exemplary embodiment.

Referring to FIG. 1, a semiconductor package 1000 according to an exemplary embodiment may include a printed circuit board (PCB) 100, a semiconductor chip 200, bonding wires 210 and a molding member 300. The semiconductor package 1000 may have a pin insertion-type (PI-type) configuration or a surface mount-type configuration.

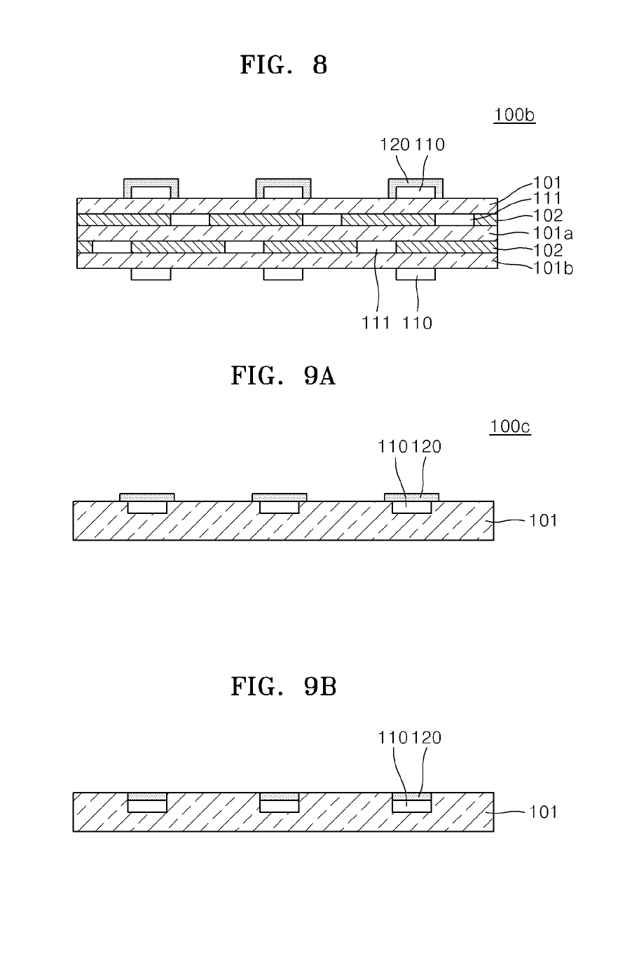

The PCB 100 may include an insulation layer 101, an interconnection portion 110, a metal layer 120 and a protection layer 130. The insulation layer 101 have a flat plate structure including a bottom surface and a top surface, and the interconnection portion 110 including a plurality of interconnection patterns may be disposed on at least one surface of the bottom surface and the top surface of the insulation layer 101. The metal layer 120 may cover the interconnection portion 110 including the plurality of interconnection patterns, and the protection layer 130 may be disposed to cover the metal layer 120 and the bottom surface and the top surface of the insulation layer 101. The PCB 100 may be a single-sided PCB or a double-sided PCB. Further, the PCB 100 may be a multi-layered PCB, as illustrated in FIG. 8. Moreover, the PCB 100 may be a rigid PCB or a flexible PCB.

The semiconductor chip 200 may be a memory chip or a logic chip and may include a single chip or at least two chips stacked sequentially. The semiconductor chip 200 may be mounted on at least one surface of a bottom surface and a top surface of the PCB 100 and may be electrically connected to the PCB 100 through the bonding wires 210. Alternatively, the semiconductor chip 200 may be a flip chip which is mounted on the PCB 100 without the use of bonding wires 210. In an exemplary embodiment, an adhesive layer (not shown) may be disposed between the semiconductor chip 200 and the PCB 100.

In response to the semiconductor chip 200 being mounted on the PCB 100 using a wire bonding technology, as illustrated in FIG. 1, the bonding wires 210 may be formed using a gold wire or an aluminum wire. The bonding wires 210 may be formed using a ball-bonding technique or a wedge-bonding technique. The bonding wires 210 may be physically and electrically connected to the PCB 100 using a thermo-compression bonding process, an ultrasonic wire bonding process, or a combination (i.e., a thermo-sonic wire bonding process) thereof.

The molding member 300 may be disposed to cover the semiconductor chip 200 and the bonding wires 210. The molding member 300 may cover the semiconductor chip 200 and the bonding wires 210 to protect the semiconductor chip 200 and the bonding wires 210 from the external environment, such as external light, external electricity and external shock. The molding member 300 may be formed to include various materials in consideration of their thermal conductivity, a coefficient of moisture absorption, a flexibility, a tensile strength and an adhesive strength. For example, the molding member 300 may be formed of a mixture of an epoxy resin material, a thermoset resin material (or a thermoplastic resin material), a silicate material, a catalyst agent and a coloring agent. In response to the semiconductor package 1000 being formed to have a plastic leaded chip carrier (PLCC) package shape or a plastic dual in-line package (PDIP) shape, the molding member 300 may be formed of a general molding material having a relatively high tensile strength and a relatively high flexibility. Further, in response to the semiconductor chip 200 being a high voltage device, the molding member 300 may be formed of a molding material having a relatively high thermal conductivity.

In an exemplary embodiment, the PCB 100 of the semiconductor package 1000 may include the metal layer 120 covering the interconnection patterns of the interconnection portion 110, thereby enhancing the reliability of the semiconductor package 1000. That is, the interconnection portion 110 of the PCB 100 may be formed of an aluminum material or a copper material. In such a case, the interconnection patterns formed of the aluminum material or the copper material may be readily contaminated and may tend to react on the protection layer 130 covering the interconnection patterns.

However, according to an exemplary embodiment, the interconnection patterns of the interconnection portion 110 are covered with the metal layer 120. Thus, the metal layer 120 may prevent the interconnection patterns of the interconnection portion 110 from being oxidized and contaminated. Accordingly, the reliability of the interconnection portion 110 disposed in the PCB 100 may be improved because of the presence of the metal layer 120.

FIGS. 2A and 2B are cross-sectional views which illustrate printed circuit boards according to an exemplary embodiment.

Referring to FIGS. 2A and 2B, each PCB 100 may include an insulation layer 101, an interconnection portion 110 and a metal layer 120.

The insulation layer 101 may be formed of a prepreg, i.e. “pre-impregnated” resin material that is fabricated to have a semi-hardening state by infiltrating thermoset resin into glass fiber. However, the insulation layer 101 is not limited to the prepreg resin material. That is, the insulation layer 101 may be formed of one of various resin materials different from the prepreg resin material. For example, the insulation layer 101 may be formed of a thermoset epoxy resin material, a thermoplastic epoxy resin material or a resin material including fillers.

The insulation layer 101 may be a rigid material such as a bismaleimide triazine (BT) resin material or a frame retardant 4 (FR-4) material. Alternatively, the insulation layer 101 may be a flexible material such as a polyimide (PI) material or a polyester (PET) material. In response to the insulation layer 101 being a flexible material, the insulation layer 101 may be formed using a reel process because the flexible material is thin and soft. In contrast, in response to the insulation layer 101 being a rigid material, the insulation layer 101 may be formed using a panel process that produces the panel. However, in an exemplary embodiment, even though the insulation layer 101 is a rigid material, the insulation layer 101 may be formed using a reel process because the rigid material has recently been provided to have a thin film shape.

The interconnection portion 110 may be formed to include a metal material such as an aluminum (Al) material or a copper (Cu) material. Alternatively, the interconnection portion 110 may be formed by patterning a metal layer such as a copper layer to form a plurality of metal patterns and by coating the metal patterns with a different metal material, for example, a gold material using an electroplating process.

The interconnection portion 110 may be disposed on at least one surface of a bottom surface and a top surface of the insulation layer 101. In response to the interconnection portion 110 being disposed on any one surface of the bottom surface and the top surface of the insulation layer 101, the PCB 100 may be referred to as having a one-layer wire pattern structure. In contrast, in response to the interconnection portion 110 being disposed on both the bottom surface and the top surface of the insulation layer 101, the PCB 100 may be referred to as having a two-layer wire pattern structure. Accordingly, FIG. 2A illustrates a one-layer wire pattern structure and FIG. 2B illustrates a two-layer wire pattern structure.

Interconnection patterns constituting the interconnection portion 110 may be formed using a subtractive process, a full additive process or a semi-additive process. The semi-additive process may be very attractive because fine patterns can be formed using the semi-additive process.

The interconnection portion 110 may be formed using an imprinting process, for example, a roll-to-roll printing process or a screen printing process. The imprinting process may be performed by preparing an inter-medium having a desired shape and by stamping out a conductive material with the inter-medium to form a plurality of conductive patterns. Recently, a nano-imprinting process other than the roll-to-roll printing process and the screen printing process has been proposed to form fine patterns.

However, the method of forming the interconnection portion 110 is not limited to the above listed processes. For example, in an exemplary embodiment, the interconnection portion 110 may be formed by etching a metal layer deposited on the insulation layer 101 using a photoresist pattern as an etch mask.

The metal layer 120 may cover the interconnection portion 110 in order to prevent the interconnection portion 110 from being oxidized and contaminated.

The metal layer 120 may include at least one of tin (Sn), nickel (Ni), titanium (Ti), titanium nitride (TiN), tantalum (Ta), tantalum nitride (TaN), titanium tungsten (TiW) and tungsten nitride (WN). However, the exemplary embodiments are not limited to the above listed materials. For example, the metal layer 120 may be formed of other reliable metal materials different from the above listed metal materials.

The metal layer 120 may be formed using any one of a plating process, a deposition process and a coating process. In the event that the metal layer 120 is formed using a plating process, the metal layer 120 may be formed to cover the interconnection portion 110 using an electroplating process that utilizes an electrolysis technique or using an electroless plating process that utilizes a reducing technique. In the event that the metal layer 120 is formed using a deposition process, the metal layer 120 may be formed using a chemical vapour deposition (CVD) process or a physical vapour deposition (PVD) process. The CVD process may extract metal atoms from chemical vapour to form a metal layer. According to the CVD process, a compound vapour gas may be sent onto a substrate in a process chamber together with a carrier gas and the compound vapour gas may be thermally decomposed on the substrate to form a thin film or may be reduced by a hydrogen gas to form the thin film. Specifically, the CVD process for forming the metal layer 120 may include a thermal CVD process that produces a compound vapour gas using a thermal energy, a plasma CVD process that decomposes a reaction gas using plasma, or a photo CVD process that decomposes a source gas using a light energy obtained from a light source such as a laser. In the event that the metal layer 120 is formed using a PVD process, the metal layer 120 may be formed of a vacuum evaporation process, a sputtering process or an ion plating process.

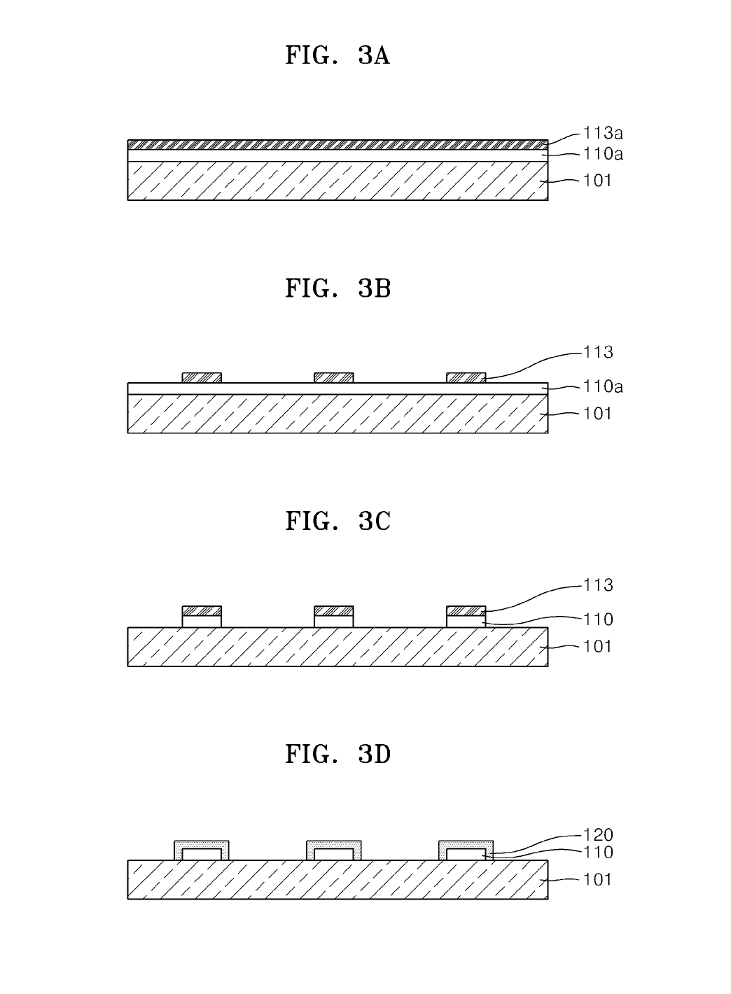

FIGS. 3A to 3D are cross-sectional views illustrating a method of fabricating a printed circuit board according to some embodiments of the inventive concept.

Referring to FIG. 3A, a basic member may be formed by pressing or cladding a copper panel 110a on an insulation layer 101, and a photoresist layer 113a may be coated on the basic member. The insulation layer 101 may be an epoxy type panel including a prepreg resin material, a thermoset epoxy material, a thermoplastic epoxy resin material, or a resin material containing fillers.

Referring to FIG. 3B, predetermined regions of the photoresist layer 113a may be exposed using a photo mask and the exposed regions of the photoresist layer 113a may be selectively removed using a developing solution to form a photoresist pattern 113. The photoresist layer 113a may be a positive resist layer, exposed regions of which are removed by a developing solution or a negative resist layer, unexposed regions of which are removed by a developing solution.

Referring to FIG. 3C, the copper panel 110a may be etched using the photoresist pattern 113a as an etch mask to form an interconnection portion 110.

Referring to FIG. 3D, the photoresist pattern 113 may be removed, and the interconnection portion 110 and the insulation layer 101 may be cleaned. Subsequently, a metal layer 120 may be formed to cover the interconnection portion 110.

The metal layer 120 may be formed to include at least one of tin (Sn), nickel (Ni), titanium (Ti), titanium nitride (TiN), tantalum (Ta), tantalum nitride (TaN), titanium tungsten (TiW) and tungsten nitride (WN).

The metal layer 120 may be formed using any one of an electroplating process, an electroless plating process, a thermal CVD process, a plasma CVD process, a photo CVD process, a vacuum evaporation process, a sputtering process and an ion plating process.

The aforementioned method is merely an example of various methods of fabricating a PCB. That is, a process for forming a protection layer (130 of FIG. 1) may be additionally performed after forming the metal layer 120.

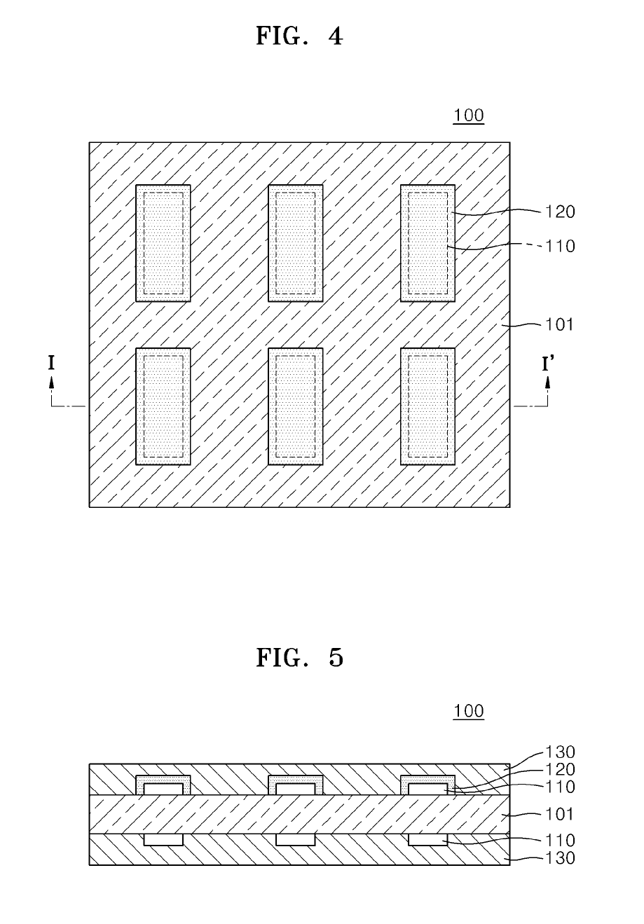

FIG. 4 is a plan view illustrating a printed circuit board according to an exemplary embodiment, and FIG. 5 is a cross-sectional view taken along a line I-I′ of FIG. 4.

Referring to FIGS. 4 and 5, a PCB 100 according to an exemplary embodiment may include an insulation layer 101, an interconnection portion 110, a metal layer 120 and a protection layer 130.

In FIGS. 4 and 5, sizes and shapes of interconnection patterns constituting the interconnection portion 110 may be exaggerated for the purpose of ease and convenience in explanation. That is, the interconnection patterns may be formed on the insulation layer 101 to have various different shapes. As illustrated in FIG. 5, the metal layers 120 may be formed to cover the interconnection patterns constituting the interconnection portions 110.

The protection layer 130 may be formed to cover a top surface and a bottom surface of the insulation layer 101 as well as a surface of the metal layer 120. The protection layer 130 may be formed to reduce a leakage current of the PCB 100. Further, the protection layer 130 may prevent the solder, which is used to mount electronic devices on the PCB 100, from being attached to unnecessary portions of the PCB 100 and may prevent the metal layer 120 from being exposed to air. That is, the protection layer 130 may prevent the metal layer 120 from being oxidized by oxygen or moisture in the air. In addition, the protection layer 130 may physically protect the PCB 100. Thus, the protection layer 130 may be a material having an adhesive property, an electrical insulation property, a heat resistant property and a solvent resistant property.

The protection layer 130 may be formed of one of a solder resist (SR) material, a dry film resist (DFR) material, an electro-deposition resist material and a screen resist material. In some embodiments, in the event that the insulation layer 101 is a rigid substrate that is formed of a rigid material such as a bismaleimide triazine (BT) resin material or a frame retardant 4 (FR-4) material, the protection layer 130 may be a solder resist (SR) layer that has an excellent printability to the insulation layer 101, an excellent resolution by development in an alkali solution, an excellent adhesive strength to a surface of the insulation layer 101, and an excellent heat resistant property when soldering. In contrast, in the event that the insulation layer 101 is a flexible substrate that is formed of a flexible material such as a polyimide (PI) material or a polyester (PET) material, the protection layer 130 may be a flexible insulation film including a polyester (PET) material, a polyimide (PI) material or a liquid crystal polymer material. In response to the flexible insulation film being stacked on the insulation layer 101, the flexible insulation film may be pressurized with thermal energy using an epoxy type adhesive agent or an acryl type adhesive agent.

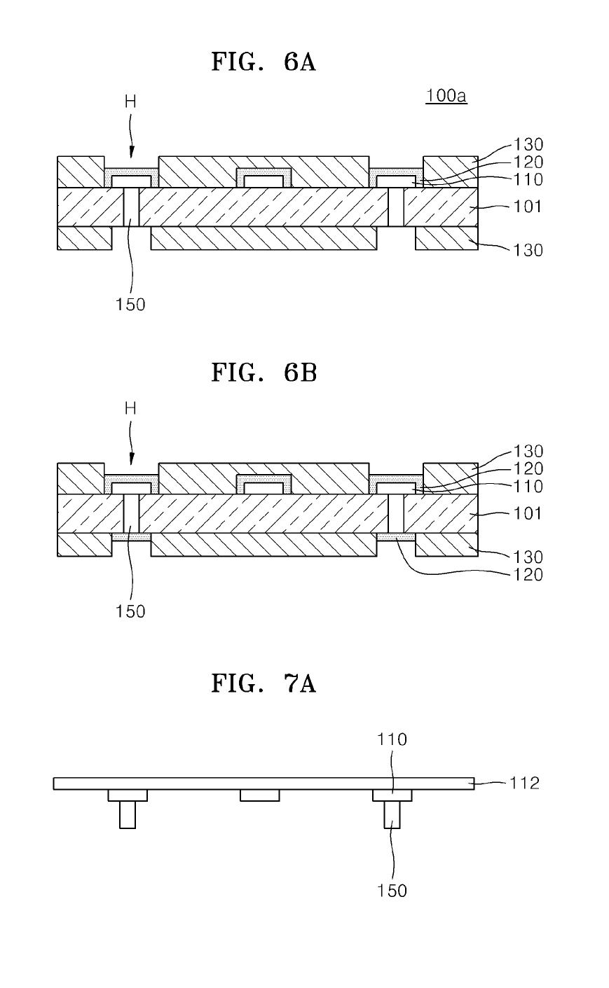

FIGS. 6A and 6B are cross-sectional views illustrating printed circuit boards according to another exemplary embodiment.

Referring to FIG. 6A, a PCB 100a according to an exemplary embodiment may include an insulation layer 101, an interconnection portion 110, a metal layer 120, through contacts 150 and a protection layer 130.

The PCB 100a may have a one-layer wire pattern structure that interconnection patterns constituting the interconnection portion 110 are disposed on only one surface of the insulation layer 101.

The interconnection portion 110 may be disposed on the insulation layer 101 to provide a normal type configuration, as illustrated in FIG. 6A. However, the exemplary embodiments are not limited thereto. That is, the interconnection portion 110 may be disposed in the insulation layer 101 to provide a buried type configuration.

The through contacts 150 may penetrate predetermined regions of the insulation layer 101 to contact the corresponding interconnection patterns of the interconnection portion 110. Bottom surfaces of the through contacts 150 may be exposed at a bottom surface of the insulation layer 101.

In the event that the interconnection portion 110 is disposed on a top surface of the insulation layer 101 as illustrated in FIG. 6A and a semiconductor chip (not shown) is mounted on the top surface of the insulation layer 101, bump lands (not shown) may be disposed on the top surface of the insulation layer 101 and solder ball lands (not shown) may be disposed on the bottom surface of the insulation layer 101 exposing the through contacts 150. On the contrary, in the event that the interconnection portion 110 is disposed on the bottom surface of the insulation layer 101, solder ball lands may be disposed on the bottom surface of the insulation layer 101 and bump lands may be disposed on the top surface of the insulation layer 101 exposing the through contacts 150.

The protection layer 130 may be disposed on the top surface and the bottom surface of the insulation layer 101. The protection layer 130 may have openings H that expose bump lands which are combined with a semiconductor chip and solder ball lands on which solder balls are attached.

The protection layer 130 may be formed using one of various processes. In an exemplary embodiment, the protection layer 130 may be formed using a photolithography process. The photolithography process may be used in formation of fine patterns such as interconnection lines and contact holes. The photolithography process may include uniformly coating a photoresist material on a substrate using a spin coating process, a spray process or a dipping process, baking the photoresist material to form a photoresist layer, exposing the photoresist layer using a photo mask, and developing the exposed photoresist layer to form a photoresist pattern. The photoresist material may be formed of a positive photoresist material or a negative photoresist material. A resolution of the photoresist pattern may depend on a wavelength of light irradiated on the photoresist layer in response to the exposure step being performed. Thus, the protection layer 130 having the openings H may be formed using an electron beam lithography process that utilizes e-beam instead of ultraviolet ray for a high resolution.

In an exemplary embodiment, the protection layer 130 may be formed using a printing process, for example, a roll-to-roll printing process or a screen printing process. That is, the openings H of the protection layer 130 may be formed using an imprinting process.

Referring to FIG. 6B, a PCB according to an exemplary embodiment may have a similar configuration to the PCB 100a of FIG. 6A. However, this exemplary embodiment may be different from the previous exemplary embodiment illustrated in FIG. 6A in terms of a configuration of the metal layer 120. That is, whereas the metal layer 120 of the PCB 100a illustrated in FIG. 6A is disposed to cover the interconnection portion 110, the metal layer 120 of the PCB illustrated in FIG. 6B may be disposed to cover the interconnection portion 110 as well as the bottom surfaces of the through contacts 150.

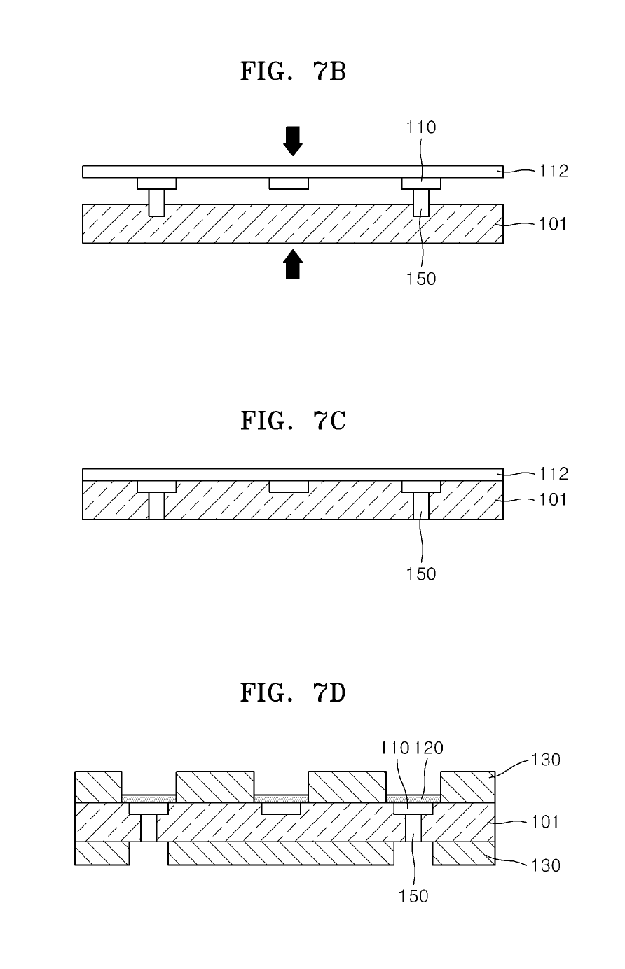

FIGS. 7A to 7D are cross-sectional views which illustrate a method of fabricating a printed circuit board according to an exemplary embodiment.

Referring to FIG. 7A, an interconnection portion 110 may be formed on a carrier substrate 112. The carrier substrate 112 may be, for example, a copper film or a copper plating film. In an exemplary embodiment, the carrier substrate 112 may be formed of another metal material which is different from a copper material.

The interconnection portion 110 may be formed to include a plurality of interconnection patterns using a plating process. This interconnection portion 110 may be formed of the same metal material as the carrier substrate 112. For example, in response to the carrier substrate 112 being formed of a copper material, the interconnection portion 110 may also be formed of a copper material. However, the exemplary embodiments are not limited thereto. That is, the interconnection portion 110 may be formed of a metal material which is different from the carrier substrate 112.

Through contacts 150 may be formed on at least one of the interconnection patterns of the interconnection portion 110. The through contacts 150 may be formed to have an appropriate height in consideration of a thickness of an insulation layer 101 which is formed in a subsequent process.

These through contacts 150 may be formed of the same material (e.g., a copper material) as the interconnection portion 110 using a plating process. However, the exemplary embodiments are not limited thereto. For example, the through contacts 150 may be formed of a different material from the interconnection portion 110 and may be formed using a different process from the plating process.

Referring to FIGS. 7B and 7C, the carrier substrate 112 including the through contacts 150 may be pressurized toward the insulation layer 101 such that the through contacts 150 penetrate the insulation layer 101. As illustrated in FIG. 7C, the carrier substrate 112 may be pressurized toward the insulation layer 101 such that the interconnection portion 110 is buried in the insulation layer 101. However, in some embodiments, the carrier substrate 112 may be pressurized toward the insulation layer 101 such that only the through contacts 150 penetrate the insulation layer 101 and the interconnection portion 110 is disposed on a top surface of the insulation layer 101 as illustrated in FIG. 6A. In such a case, a thickness of the insulation layer 101 may be determined to be equal to a height of the through contacts 150.

Referring to FIG. 7D, the PCB according to an exemplary embodiment may have a similar configuration as the PCB 100a illustrated in FIG. 6A. However, the PCB according to the exemplary embodiment may be different from the exemplary embodiment illustrated in FIG. 6A in terms of a position of the interconnection portion 110. That is, the interconnection portion 110 of the exemplary embodiment may be buried in the insulation layer 101 whereas the interconnection portion 110 of the previous exemplary embodiment illustrated in FIG. 6A is disposed on a top surface of the insulation layer 101.

As described above, the PCB may be referred to as a buried type PCB in response to the interconnection portion 110 being buried in the insulation layer 101, and the PCB may be referred to as a normal type PCB in response to the interconnection portion 110 being disposed on a surface of the insulation layer 101.

Referring again to FIG. 7D, after the insulation layer 101 is combined with the through contacts 150, the carrier substrate 112 may be removed from the interconnection portion 110 using an etch process.

After removal of the carrier substrate 112, a metal layer 120 may be formed to cover the interconnection portion 110. The metal layer 120 may be formed to cover the top surfaces of the buried interconnection patterns of the interconnection portion 110 and to extend onto portions of the top surface of the insulation layer 101, as illustrated in FIG. 7D.

A protection layer 130 may be formed on the top surface and the bottom surface of the insulation layer 101. The protection layer 130 may be formed to include a plurality of openings that expose the metal layer 120 and bottom surfaces of the through contacts 150. In an exemplary embodiment, the metal layer 120 may be formed after the protection layer 130 is formed. The protection layer 130 may be formed using one of various processes, as described with reference FIGS. 4, 5 and 6A.

A method of forming the through contacts 150 is not limited to the aforementioned method. For example, the through contacts 150 may be formed by forming a photoresist pattern exposing portions of the bottom surface of the insulation layer 101, by applying an etch process to the bottom surface of the insulation layer 101 to form through via holes, and by filling the through via holes with a metal material.

FIG. 8 is a cross-sectional view which illustrates a printed circuit board according to an exemplary embodiment.

Referring to FIG. 8, a PCB 100b according to an exemplary embodiment may be a multi-layered PCB including at least one internal interconnection pattern layer 111 disposed in an insulation layer 101.

Recently, highly reliable and high performance PCBs have been increasingly in demand with the development of highly integrated and faster operating semiconductor chips. In response to such a demand, the multi-layered PCB 100b illustrated in FIG. 8 may be used. The multi-layered PCB 100b may be fabricated and evaluated layer by layer to improve a fabrication yield thereof, and interconnection patterns located in different layers may be accurately connected to each other to fabricate a highly integrated and small PCB.

The internal interconnection pattern layer 111 illustrated in FIG. 8 is merely an example of suitable internal interconnection pattern layers. That is, the internal interconnection pattern layer 111 may be modified to have various configurations and shapes in the insulation layer 101.

The internal interconnection pattern layer 111 may include a plurality of layers which are separated from each other. The internal interconnection pattern layer 111 may be formed of the same material as an interconnection portion 110, which is disposed on the insulation layer 101.

In an exemplary embodiment, the insulation layer may include a plurality of insulation layers 101, 101a and 101b which are stacked, and internal insulation layers 102 may be disposed between the insulation layers 101, 101a and 101b. The internal interconnection pattern layer 111 may also be disposed between the insulation layers 101, 101a and 101b.

The internal insulation layers 102 may be formed of a prepreg resin material that is fabricated to have a semi-hardening state by infiltrating thermoset resin into glass fiber. In an exemplary embodiment, the insulation layers 101, 101a and 101b may be formed of the same material as the internal insulation layers 102. Alternatively, the insulation layers 101, 101a and 101b may be formed of a different material from the internal insulation layers 102.

The PCB 100b according to an exemplary embodiment may include the interconnection portion 110, the internal interconnection pattern layer 111 and the insulation layers 101, 101a and 101b which are alternately stacked. Although not shown in the drawings, the PCB 100b may further include vias that penetrate the insulation layers 101, 101a and 101b to electrically connect the internal interconnection pattern layer 111 and the interconnection portion 110 with each other. Via holes for forming the vias may be formed using a mechanical drill process or a chemical etch process. Alternatively, in the event that a diameter of the via holes is reduced, the via holes may be formed using a laser process to accurately control the diameter of the via holes.

A method of fabricating the multi-layered PCB 100b will be described hereinafter. The method of fabricating the multi-layered PCB 100b may include (a) preparing a copper clad laminate (CCL) having an insulation layer 101a and a copper film formed on a top surface and a bottom surface of the insulation layer 101a, (b) patterning the copper film to form internal interconnection patterns 111, (c) forming a copper film on a top surface of an insulation layer 101 and on a bottom surface of an insulation layer 101b and pressurizing the insulation layers 101 and 101b with a thermal energy to combine with the insulation layer 101a after aligning the insulation layers 101 and 101b with the internal interconnection patterns 111, (d) pattering the copper film to form an interconnection portion 110, (e) patterning the insulation layers using a laser process to form via holes, and (f) forming a conductive layer in the via holes using a plating process to electrically connect the interconnection portion 110 and the internal interconnection patterns 111 to each other. Further, a solder resist layer acting as a protection layer 130 may be additionally formed on the insulation layers 101 and 101b, or additional insulation layers may be formed on the insulation layers 101 and 101b.

The PCB 100b may be formed by stacking a plurality of internal layers and a plurality of external layers. Thus, it may be important to accurately form the via holes. The PCB 100b may be formed of thin materials and a prepreg resin material. Thus, in response to the prepreg resin material being cured or hardened, the PCB 100b may be deformed or warped due to a tensile stress generated from the prepreg resin material. In such a case, the internal interconnection patterns 111 and the interconnection portion 110 may be mismatched to cause undesired electrical disconnection or shortage between the internal interconnection patterns 111 and the interconnection portion 110. This means that the matching technique between the interconnection portion 110 and the internal interconnection patterns 111 is important and critical.

A stacking step for forming the PCB 100b may include a first stacking step and a second stacking step. In the first stacking step, an internal layer material and a prepreg resin material may be stacked. In the second stacking step, a copper film may be disposed on top and bottom surfaces of a substrate formed by the first stacking step, and a mirror plate (also, referred to as a press plate or a texture plate) and a cushion pad may be put on the copper film for a press process.

The stacking step for forming the PCB 100b may be performed using a mass lamination technique or a pin lamination technique. The mass lamination technique means the mass production technique of a multi-layered PCB which is formed by simultaneously stacking a prepreg resin material and a copper film on top and bottom surfaces of an internal panel having predetermined patterns. The mass lamination technique may be used in fabrication of a four-layered PCB including a single internal layer material. This is because the four-layered PCB can be fabricated even without the use of an accurate alignment since the four-layered PCB has a single internal layer material. The pin lamination technique means the mass production technique of a multi-layered PCB, which is matched or aligned by forming a guide hole in external layers and internal layers and by stacking each layer material on a reference pin, is provided in press equipment for being stacked. After the stacking process is finished using the mass lamination technique or the pin lamination technique, the substrate including the stacked materials may be inserted into a space between heating plates and may be pressurized and heated during a predetermined time. Subsequently, a targeting process may be performed to form a reference hole in a target guide mark (acting as a reference point of a drill process) of the internal layers using a target drill technique utilizing laser, and a trimming process may be performed to remove resin materials and copper film which are streamed out of the substrate.

FIGS. 9A and 9B are cross-sectional views illustrating printed circuit boards according to an exemplary embodiment.

Referring to FIG. 9A, the exemplary embodiment illustrates a buried type PCB 100c including an insulation layer 101 and an interconnection portion 110 disposed in the insulation layer 101.

Recently, highly reliable and high performance PCBs have been increasingly in demand with the development of highly integrated and faster semiconductor chips. In response to such a demand, the buried type PCB 100c illustrated in FIG. 9A may be used.

The interconnection portion 110 may be formed using a different method from the exemplary embodiment described with reference to FIG. 2A. That is, the method of fabricating the PCB of FIG. 2A may include forming a metal layer on the insulation layer 101, forming a photoresist layer on the metal layer, patterning the photoresist layer using a photolithography process to form a photoresist pattern, etching the metal layer using the photoresist pattern as an etch mask, and removing the photoresist pattern.

Alternatively, a method of fabricating the buried type PCB 100c of FIG. 9A may be similar to the fabrication method described with reference to FIGS. 7A to 7D. That is, the method of fabricating the buried type PCB 100c of FIG. 9A may include forming an interconnection portion 110 on the carrier substrate 112, pressing the carrier substrate 112 such that the interconnection portion 110 is buried in the insulation layer 101, and removing the carrier substrate 112 from the interconnection portion 110.

In an exemplary embodiment, the method of fabricating the buried type PCB 100c of FIG. 9A may include etching predetermined regions of the insulation layer 101 to form recessed regions and forming the interconnection portion 110 in the recessed regions.

In addition, a metal layer 120 may be formed to cover top surfaces of interconnection patterns constituting the interconnection portion 110. The metal layer 120 may extend onto a top surface of the insulation layer 101 adjacent to the interconnection patterns, as illustrated in FIG. 9A.

Referring to FIG. 9B, a buried type PCB according to an exemplary embodiment may have a different configuration from the buried type PCB 100c of FIG. 9A. That is, according to the exemplary embodiment, both the interconnection portion 110 and the metal layer 120 may be buried in the insulation layer 101, as illustrated in FIG. 9B.

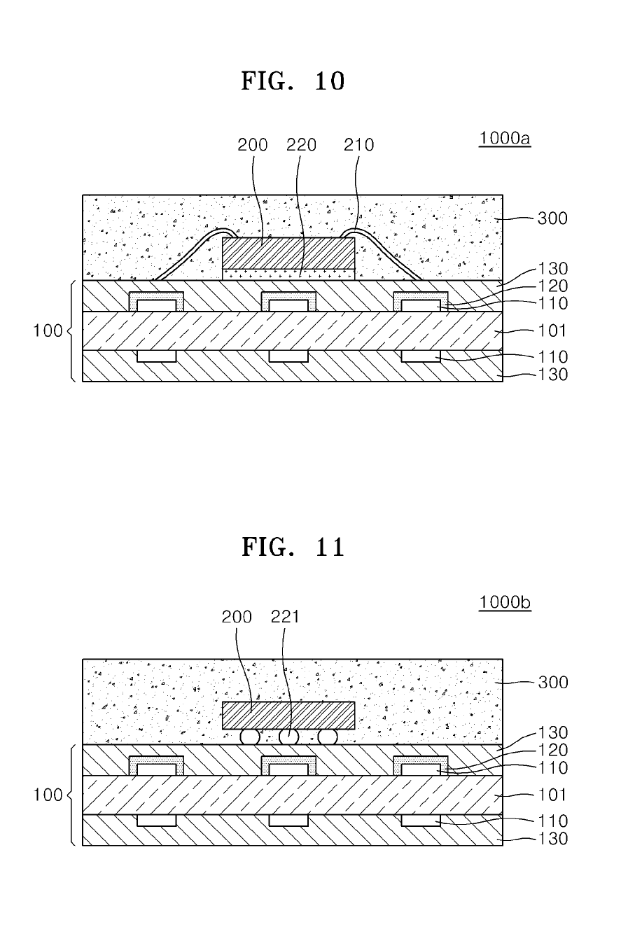

FIG. 10 is a cross-sectional view which illustrates a semiconductor package according to an exemplary embodiment.

Referring to FIG. 10, a semiconductor package 1000a according to an exemplary embodiment may include a PCB 100, a semiconductor chip 200 mounted on a surface of the PCB 100, an adhesive layer 220 disposed between the semiconductor chip 200 and the PCB 100, and a molding member 300 encapsulating the semiconductor chip 200.

The adhesive layer 220 may be formed of a hard solder material such as an alloy material containing lead (Pb) and antimony (Sb) or a polymer material such as epoxy resin or polyimide.

In an exemplary embodiment, the adhesive layer 220 may be a die attach film (DAF). A material of the DAF may be a low elastic material including polyimide or polyamide-imide having an excellent heat resistant property and siloxane introduced into the polyimide or polyamide-imide. Alternatively, the DAF may include an epoxy resin material and a polyimide silicon material having an excellent heat resistant property, and the polyimide silicon material may be obtained by mixing a siloxane modified polyamide-imide material and a compound material having at least two maleimide groups.

In an exemplary embodiment, the adhesive layer 220 may be formed using a dispensing technique or a wafer backside lamination technique.

FIG. 11 is a cross-sectional view which illustrates a semiconductor package according to an exemplary embodiment.

Referring to FIG. 11, a semiconductor package 1000b according to an exemplary embodiment may include a PCB 100, a semiconductor chip 200 mounted on a surface of the PCB 100, and a molding member 300 encapsulating the semiconductor chip 200.

The semiconductor chip 200 may be mounted on the PCB 100 using a flip-chip bonding technique. That is, a front surface of the semiconductor chip 200 may face the PCB 100, and the semiconductor chip 200 may be electrically connected to the PCB 100 through bumps 221.

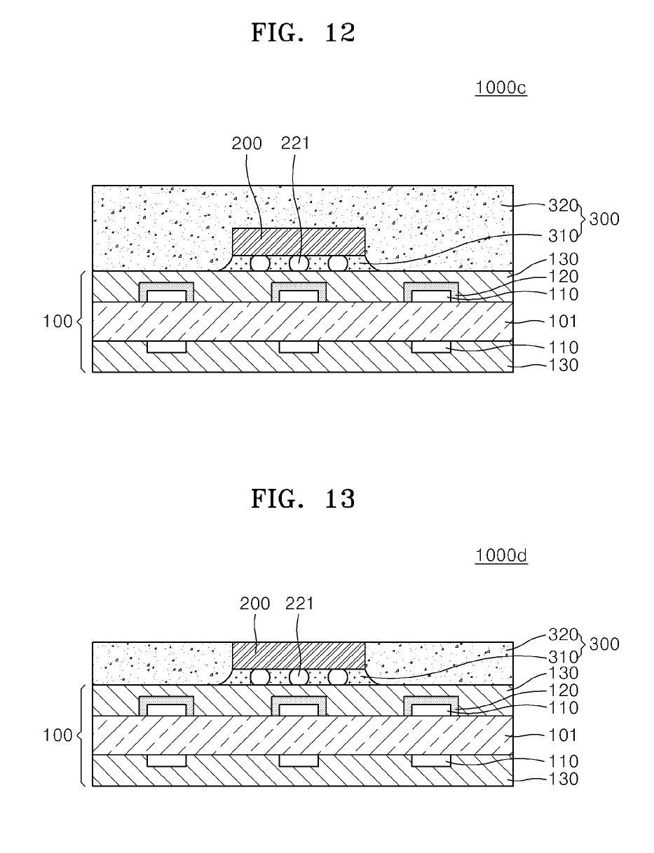

The molding member 300 may encapsulate the semiconductor chip 200 to protect the semiconductor chip 200 from an external environment, as described with reference to FIG. 1. The molding member 300 may be formed of a mixture of an epoxy resin material, a thermoset resin material (or a thermoplastic resin material), a silicate material, a catalyst agent and a coloring agent. In the event that the semiconductor package 1000b is fabricated using a flip-chip bonding technique as illustrated in FIG. 11, the molding member 300 may be formed using a molded under fill (MUF) process. According to the molded under fill (MUF) process, the molding member 300 covering the semiconductor chip 200 and filling a space between the semiconductor chip 200 and the PCB 100 may be formed using a single process step without use of two separate processes. In such a case, the molding member 300 covering the semiconductor chip 200 may be the same material as the molding member 300 filling a space between the semiconductor chip 200 and the PCB 100. However, the molding member 300 may be formed using a different process from the molded under fill (MUF) process, as illustrated in FIG. 12.

FIG. 12 is a cross-sectional view which illustrates a semiconductor package according to an exemplary embodiment.

Referring to FIG. 12, a semiconductor package 1000c according to the exemplary embodiment may have a similar configuration to the semiconductor package 1000b illustrated in FIG. 11. The exemplary t embodiment is different from the previous exemplary embodiment illustrated in FIG. 11 in terms of a process of forming a molding member 300. That is, in the exemplary embodiment, an under fill material 310 between the semiconductor chip 200 and the PCB 100 and an external molding member 320 on the semiconductor chip 200 may be separately formed.

Specifically, the under fill material 310 may be formed to fill a space between the semiconductor chip 200 and the PCB 100, and the external molding member 320 may be formed to cover the semiconductor chip 200. The under fill material 310 and the external molding member 320 may constitute a molding member 300. In such a case, the under fill material 310 and the external molding member 320 may be formed of the same material. However, in an exemplary embodiment, the under fill material 310 may be formed of a different material from the external molding member 320.

FIG. 13 is a cross-sectional view which illustrates a semiconductor package according to an exemplary embodiment.

Referring to FIG. 13, a semiconductor package 1000d according to an exemplary embodiment may have a similar configuration to the semiconductor package 1000c illustrated in FIG. 12. The exemplary embodiment is different from the previous exemplary embodiment illustrated in FIG. 12 in terms of a shape of a molding member 300. That is, according to the exemplary embodiment, an external molding member 320 of the molding member 300 may be formed to expose a top surface of the semiconductor chip 200.

FIG. 14 is a cross-sectional view which illustrates a semiconductor package according to an exemplary embodiment.

Referring to FIG. 14, a semiconductor package 1000e according to the exemplary embodiment may include a PCB 100, a semiconductor chip 200 mounted on a surface of the PCB 100, a molding member 300 surrounding sidewalls and a bottom surface of the semiconductor chip 200, and a heat sink 400 disposed on top surfaces of the semiconductor chip 200 and the molding member 300.

The heat sink 400 disposed on the top surface of the semiconductor chip 200 may be formed to include a metal material, a metal nitride material, a ceramic material, a resin material, or a combination thereof. For example, the heat sink 400 may be formed to include an aluminum (Al) material, an aluminum alloy material, a copper (Cu) material, a copper alloy material, an aluminum oxide (Al2O3) material, a beryllium oxide (BeO) material, an aluminum nitride (AlN) material, a silicon nitride (SiN) material, an epoxy resin material, or a combination thereof. Further, a size and a shape of the heat sink 400 may be appropriately changed for efficient heat radiation.

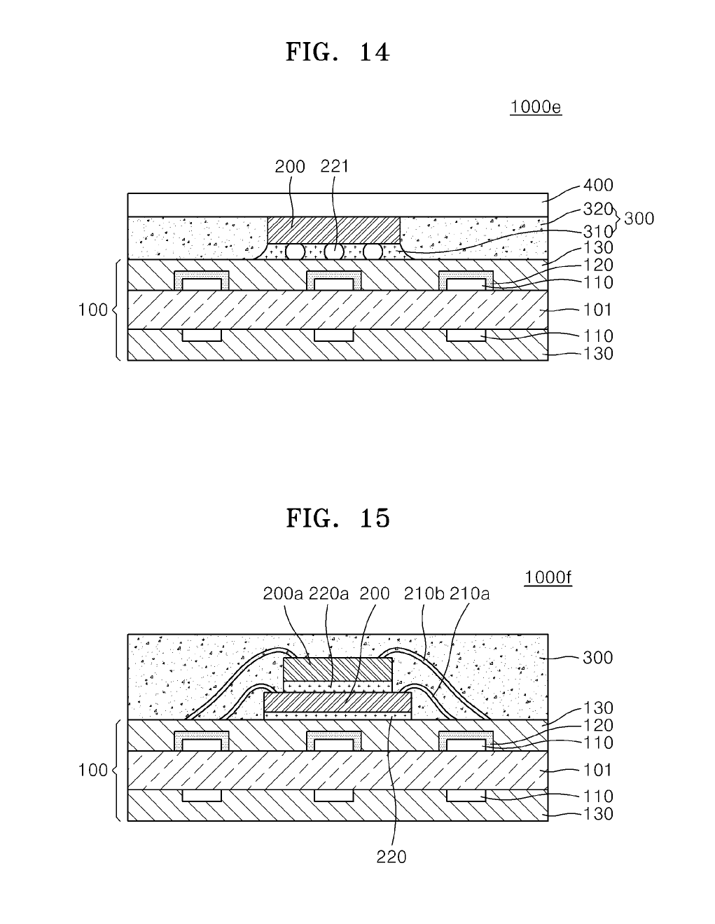

FIG. 15 is a cross-sectional view which illustrates a semiconductor package according to an exemplary embodiment.

Referring to FIG. 15, a semiconductor package 1000f according to an exemplary embodiment may include a PCB 100, a semiconductor chip 200 mounted on a surface of the PCB 100, an upper semiconductor chip 200a stacked on the semiconductor chip 200, an adhesive layer 220a disposed between the semiconductor chip 200 and the upper semiconductor chip 200a, bonding wires 210a and 210b electrically connecting the semiconductor chip 200 and the upper semiconductor chip 200a to the PCB 100, and a molding member 300 covering the semiconductor chip 200 and the upper semiconductor chip 200a.

The semiconductor package 1000f may correspond to a stack package in which a plurality of semiconductor chips are stacked, in order to increase a packing density and to minimize a thickness thereof. Thus, the semiconductor package 1000f may be widely employed in personal computers, notebook computers, mobile phones, and portable audio/video systems.

The semiconductor package 1000f may be fabricated by embedding at least two semiconductor chips in a single package or by directly stacking at least two semiconductor chips on the PCB 100 without use of a lead frame.

The semiconductor chip 200 may be attached to a surface of the PCB 100, and the semiconductor chip 200 may be electrically connected to the PCB 100 through the first bonding wires 210a. Further, the upper semiconductor chip 200a may be attached to a top surface of the upper semiconductor chip 200a using the adhesive layer 220a, and the upper semiconductor chip 200a may be electrically connected to the PCB 100 through the second bonding wires 210b. Moreover, the semiconductor chip 200, the upper semiconductor chip 200a, the first bonding wires 210a and the second bonding wires 210b may be encapsulated by the molding member 300.

In the exemplary embodiment, the semiconductor package 1000f may be fabricated using a wire bonding process as illustrated in FIG. 15. However, in some exemplary embodiments, the semiconductor chip 200 may be mounted on the PCB 100 using a flip-chip bonding technique without use of the first bonding wires 210a.

The adhesive layer 220a may bond a top surface of the semiconductor chip 200 to a bottom surface of the upper semiconductor chip 200a. The adhesive layer 220a may play an important role. This is because a weak adhesive strength of the adhesive layer 220a leads to an unstable size of the semiconductor package 1000f, or deformation of the semiconductor package 1000f. As a result, the bonding wires 210a and 210b and/or the semiconductor chips 200 and 200a may be damaged to degrade the reliability of the semiconductor package 1000f.

In an exemplary embodiment, the adhesive layer 220a may be a die attach film (DAF). A material of the DAF may be a low elastic material which includes polyimide or polyamide-imide having an excellent heat resistant property and siloxane introduced into the polyimide or polyamide-imide. Alternatively, the DAF may include an epoxy resin material and a polyimide silicon material having an excellent heat resistant property, and the polyimide silicon material may be obtained by mixing a siloxane modified polyamide-imide material and a compound material having at least two maleimide groups.

In an exemplary embodiment, the adhesive layer 220a may be formed using a dispensing technique or a wafer backside lamination technique.

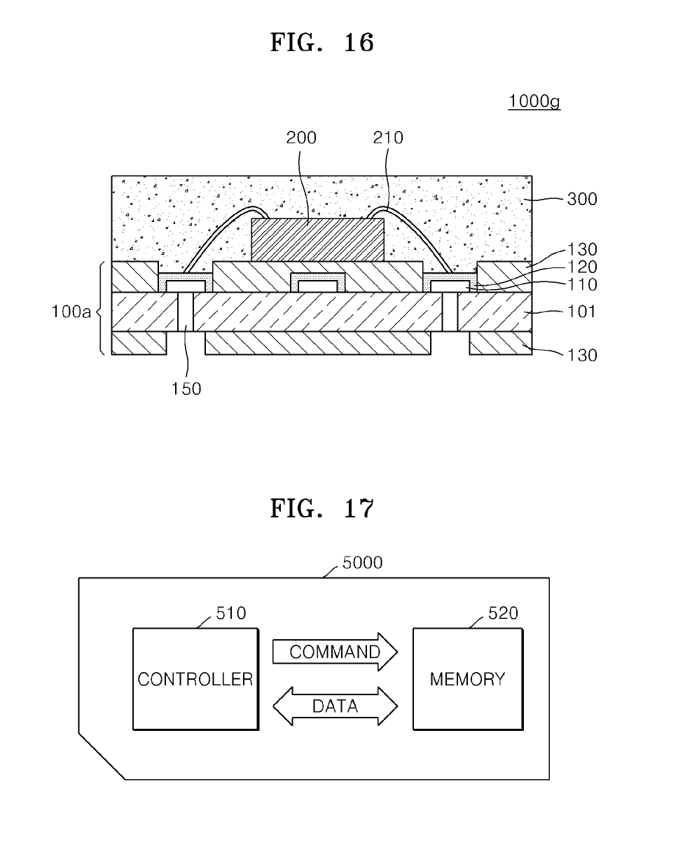

FIG. 16 is a cross-sectional view which illustrates a semiconductor package according to an exemplary embodiment.

Referring to FIG. 16, a semiconductor package 1000g according to an exemplary embodiment may include PCB 100a, a semiconductor chip 200 mounted on a surface of the PCB 100a, and a molding member 300 encapsulating the semiconductor chip 200.

The PCB 100a may correspond to the PCB having a one-layer wire pattern structure, which is described with reference to FIG. 6A. That is, the PCB 100a may include the insulation layer 101, the interconnection portion 110, the metal layer 120, the protection layer 130 and the through contacts 150 which are described with reference to FIG. 6A. Accordingly, the interconnection portion 110 and the metal layer 120 may be disposed on a top surface of the insulation layer 101, and the through contacts 150 may penetrate the insulation layer 101 to contact the interconnection patterns of the interconnection portion 110. Bottom ends of the through contacts 150 may be exposed at a bottom surface of the insulation layer 101. Alternatively, the interconnection portion 110 and the metal layer 120 may be disposed on a bottom surface of the insulation layer 101, and the through contacts 150 may be exposed at the top surface of the insulation layer 101.

Internal circuits or electronic elements formed in the semiconductor chip 200 may be electrically connected to the metal layer 120 of the PCB 100a through bonding wires 210. The semiconductor chip 200 may be a memory chip such as a dynamic random access memory (DRAM) chip or a flash memory chip or a logic chip such as a controller chip.

As described above, the semiconductor chip 200 may be electrically connected to the PCB 100a through the bonding wires 210. Thus, gold (Au) plate pads (not shown) may be formed on the metal layer 120 to reduce a contact resistance value of the bonding wires 210.

Solder balls (not shown) may be attached to the exposed bottom surfaces of the through contacts 150. Further, additional gold (Au) plate pads (not shown) may also be disposed between the through contacts 150 and the solder balls to reduce contact resistance values between the through contacts 150 and the solder balls.

FIG. 17 is a block diagram which illustrates a memory card including a semiconductor package according to an exemplary embodiment.

Referring to FIG. 17, the memory card 5000 may include a controller 510 and a memory 520 that communicate with each other using electrical signals. For example, in response to the controller 510 sending a command to the memory 520, the memory 520 may send data to the controller 510 or may receive data from the controller 510.

At least one of the controller 510 and the memory 520 may be provided to have a configuration of any one of the semiconductor packages described with reference to FIGS. 1 to 16.

The memory card 5000 may be any one of various memory cards. For example, the memory card 5000 may correspond to one of a memory stick card, a smart media (SM) card, a secure digital (SD) card, a mini-secure digital card and a multimedia card (MMC) which are widely used in various electronic systems.

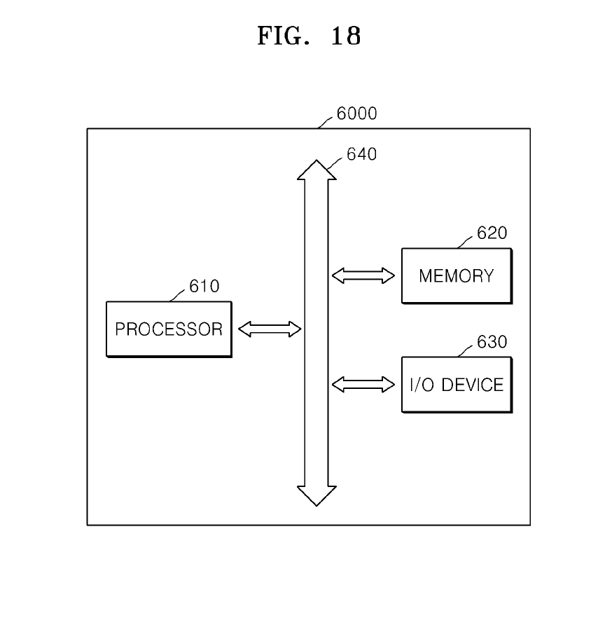

FIG. 18 is a block diagram illustrating a system which includes a semiconductor package according to an exemplary embodiment.

Referring to FIG. 18, the system 6000 may include a processor 610, a memory 620 and an input/output (I/O) device 630 that communicate with each other through a bus 640.

The processor 610 may execute program files and may control operations of the system 6000.

The memory 620 may store codes and data for operations of the processor 610 therein. At least one of the processor 610 and the memory 620 may be provided to have a configuration of any one of the semiconductor packages described with reference to FIGS. 1 to 16.

The input/output (I/O) device 630 may receive external data or may output the data processed in the system 6000. That is, the system 6000 may communicate with external device, such as a personal computer or a network device through I/O device 630.

The system 6000 may be applied to mobile phones, MP3 players, navigators, solid state disk (SSD) drivers, or the like.

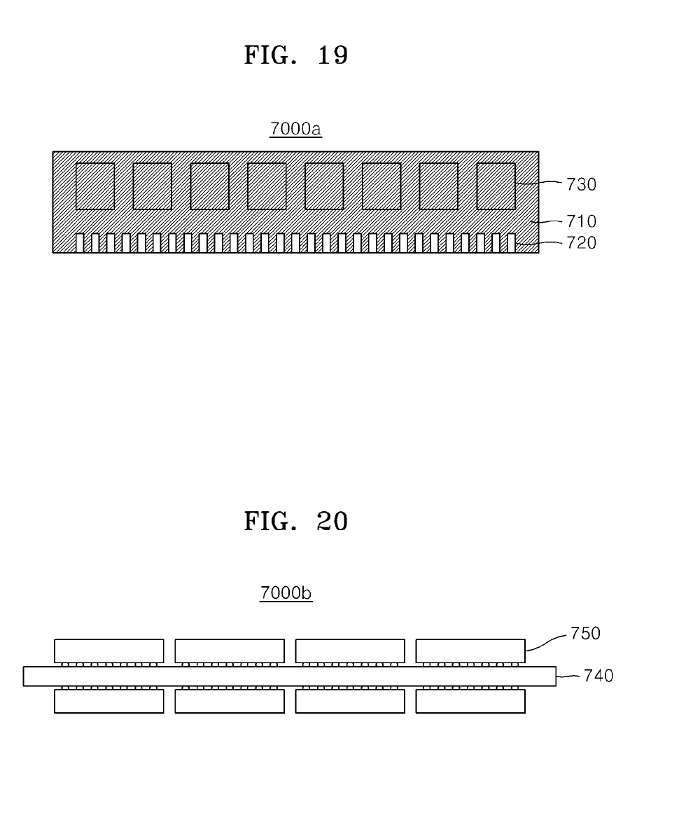

FIG. 19 is a plan view which illustrates a semiconductor module including a plurality of semiconductor packages according to some embodiments of the inventive concept.

Referring to FIG. 19, the semiconductor module 7000a may include a module board 710, a plurality of contact terminals 720, and a plurality of semiconductor packages 730.

The module board 710 may be one of the PCBs 100 and 100a described with reference to FIGS. 1 to 9. The contact terminals 720 may be disposed at one side of the module board 710 and may be electrically connected to the semiconductor packages 730.

The semiconductor packages 730 may be mounted on the module board 710. At least one of the semiconductor packages 730 may be a semiconductor package including one of the PCBs illustrated in FIGS. 1 to 9 or may be one of the semiconductor packages illustrated in FIGS. 10 to 16.

FIG. 20 is a cross-sectional view illustrating a semiconductor module which includes a plurality of semiconductor packages according to an exemplary embodiment.

Referring to FIG. 20, the semiconductor module 7000b may include a module board 740 and a plurality of semiconductor packages 750 mounted on the module board 740.

The module board 740 may be one of the PCBs 100 and 100a illustrated in FIGS. 1 to 9. At least one of the semiconductor packages 750 may be a semiconductor package including one of the PCBs illustrated in FIGS. 1 to 9 or may be one of the semiconductor packages illustrated in FIGS. 10 to 16.

While the inventive concept has been particularly shown and described with reference to exemplary embodiments thereof, it will be understood that various changes in form and details may be made therein without departing from the spirit and scope of the following claims.

What is claimed is:

1. A printed circuit board comprising:
an insulation layer having a flat plate shape and including a top surface and a bottom surface;
an interconnection portion formed on at least one of the top and bottom surfaces of the insulation layer, the interconnection portion including a plurality of interconnection patterns; and
a metal layer covering the plurality of interconnection patterns of the interconnection portion.

2. The printed circuit board of claim 1, further comprising a protection layer covering the top and bottom surfaces of the insulation layer and a surface of the metal layer.

3. The printed circuit board of claim 2, wherein the protection layer includes any one of a solder resist (SR) material, a dry film resist (DFR) material, an electro-deposition resist material and a screen resist material.

4. The printed circuit board of claim 1, wherein the insulation layer includes at least one internal interconnection pattern layer disposed therein.

5. The printed circuit board of claim 1, wherein the interconnection portion is disposed in the insulation layer to provide a buried type of configuration or is disposed on a surface of the insulation layer to provide a different type of configuration.

6. The printed circuit board of claim 1, wherein the interconnection portion includes an aluminum material or a copper material.

7. The printed circuit board of claim 1, wherein the metal layer includes at least one of a tin (Sn) material, a nickel (Ni) material, a titanium (Ti) material, a titanium nitride (TiN) material, a tantalum (Ta) material, a tantalum nitride (TaN) material, a titanium tungsten (TiW) material and a tungsten nitride (WN) material.

8. A semiconductor package comprising:
a printed circuit board including a plurality of interconnection patterns and a metal layer covering the plurality of interconnection patterns;
a semiconductor chip mounted on at least one of a top surface and a bottom surface of the printed circuit board using a wire bonding technique or a flip-chip bonding technique; and
a molding member covering at least one of the top and bottom surfaces of the printed circuit board.

9. The semiconductor package of claim 8,
wherein the printed circuit board further includes an insulation layer having a flat plate shape and having a top surface and a bottom surface and an interconnection portion formed on at least one of the top and bottom surfaces of the insulation layer, the interconnection portion including the plurality of interconnection patterns; and
wherein the interconnection portion is disposed in the insulation layer to provide a buried type of configuration or is disposed on a surface of the insulation layer to provide a different type of configuration.

10. The semiconductor package of claim 8, further comprising an adhesive layer disposed between the printed circuit board and the semiconductor chip.

11. The semiconductor package of claim 8, wherein the metal layer of the printed circuit board includes at least one of a tin (Sn) material, a nickel (Ni) material, a titanium (Ti) material, a titanium nitride (TiN) material, a tantalum (Ta) material, a tantalum nitride (TaN) material, a titanium tungsten (TiW) material and a tungsten nitride (WN) material.

12. The semiconductor package of claim 8, wherein the molding member is configured to expose a top surface of the semiconductor chip.

13. The semiconductor package of claim 8,
wherein the molding member includes an internal molding member filling a space between the semiconductor chip and the printed circuit board and an external molding member covering the semiconductor chip; and
wherein the internal molding member and the external molding member include the same material.

14. The semiconductor package of claim 8, wherein the molding member includes an external molding member covering the semiconductor chip and an under-fill material filling a space between the semiconductor chip and the printed circuit board.

15. The semiconductor package of claim 8, further comprising at least one upper semiconductor chip stacked on a surface of the semiconductor chip opposite to the printed circuit board.

16. A printed circuit board comprising:
an interconnection portion including a plurality of interconnection patterns; and
a metal layer covering the plurality of interconnection patterns of the interconnection portion, wherein the metal layer includes at least one of a tin (Sn) material, a nickel (Ni) material, a titanium (Ti) material, a titanium nitride (TiN) material, a tantalum (Ta) material, a tantalum nitride (TaN) material, a titanium tungsten (TiW) material and a tungsten nitride (WN) material.

17. The printed circuit board of claim 16, further comprising an insulation layer having a flat plate shape and including a top surface and a bottom surface.

18. The printed circuit board of claim 17, wherein the interconnection portion is formed on at least one of top and bottom surfaces of the insulation layer.

19. The printed circuit board of claim 18, further comprising a protection layer covering the top and bottom surfaces of the insulation layer and a surface of the metal layer.

20. The printed circuit board of claim 19, wherein the protection layer includes any one of a solder resist (SR) material, a dry film resist (DFR) material, an electro-deposition resist material and a screen resist material.
